(19) United States
(12) Patent Application Publication
(10) Pub. No.: US 2026/0090410 A1
(43) Pub. Date: Mar. 26, 2026

(54) EMBEDDED CHANNELS IN A GLASS CORE

(71) Applicant: Intel Corporation, Santa Clara, CA (US)

(72) Inventors: Jeremy D. ECTON, Gilbert, AZ (US); Jefferson Kaplan, Gilbert, AZ (US); Brandon C. MARIN, Gilbert, AZ (US); Srinivas Venkata Ramanuja PIETAMBARAM, Chandler, AZ (US); Gang DUAN, Chandler, AZ (US)

(21) Appl. No.: 18/891,958

(22) Filed: Sep. 20, 2024

(51) Int. Cl. H01L 23/538; H01L 23/00; H01L 23/15; H01L 25/10

(52) U.S. Cl. CPC H10W 70/611; H10W 70/635; H10W 70/692; H10W 90/00; H10W 90/724

(57) ABSTRACT

Embodiments disclosed herein include an apparatus that includes a substrate with an edge surface. In an embodiment, the substrate includes a glass layer, and a via is formed through a thickness of the substrate. In an embodiment, a recess is formed into the edge surface. In an embodiment, a height of the recess measured in a direction from a bottom of the substrate to a top of the substrate is greater than a depth of the recess.

### BACKGROUND

Electronics packaging substrates may include a core. Existing core materials include organic dielectrics that comprise fiber reinforcement materials. As devices continue to scale in complexity, alternative core materials are desired. For example, package cores that include solid glass layers may be one potential option. Glass cores enables stiffer substrates, flatter surfaces, and improved dimensional stability.

However, glass substrates that are used for the core are more fragile than existing organic core materials. Singulation of glass core substrates into individual units can be particularly problematic. For example, conventional mechanical singulation processes may result in defect generation (e.g., cracks, seware defects, etc.) as well as dielectric delamination.

### BRIEF DESCRIPTION OF THE DRAWINGS

FIG. 1A is a cross-sectional illustration of a glass core substrate with a recess into an edge surface of the glass core substrate with a single fused interface, in accordance with an embodiment.

FIG. 1B is a cross-sectional illustration of a glass core substrate with a recess into an edge surface of the glass core substrate with two fused interfaces, in accordance with an embodiment.

FIG. 1C is a cross-sectional illustration of a glass core substrate with a recess into an edge surface of the glass core substrate with a sloped profile, in accordance with an embodiment.

FIG. 2 is a cross-sectional illustration of a package substrate with a glass core substrate with a recess into an edge surface of the glass core substrate, in accordance with an embodiment.

FIG. 3A-3E are cross-sectional illustrations depicting a process for forming package substrates with a glass core substrate that includes cavities to enable improved singulation from the panel, in accordance with an embodiment.

FIG. 4 is a flow diagram describing a process for forming a package substrate with a glass core substrate that includes a recess into an edge surface of the glass core substrate, in accordance with an embodiment.

FIG. 5A-5F are cross-sectional illustrations depicting a process for forming a package substrate with a glass core substrate with two fused interfaces and a recess along an edge surface of the glass core substrate, in accordance with an embodiment.

FIG. 6 is a flow diagram describing a process for forming a package substrate with a glass core substrate that includes a recess into an edge surface of the glass core substrate and two fused interfaces, in accordance with an embodiment.

FIG. 7 is a cross-sectional illustration of an electronic system with a package substrate that includes a glass core substrate with a recess coupled to a board, in accordance with an embodiment.

FIG. 8 is a schematic of a computing device built in accordance with an embodiment.

### EMBODIMENTS OF THE PRESENT DISCLOSURE

Described herein are package substrates that include a glass core substrate with a recess into an edge surface of the glass core substrate, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, glass substrates used for package cores provides multiple advantages compared to organic dielectric substrates. For example, glass substrate cores may be stiffer, have flatter surfaces, and improved dimensional stability. However, the singulation process used in existing package substrate assembly flows may use a mechanical sawing process. Such mechanical sawing is not compatible with glass substrates since the sawing can lead to cracking, seware defects, dielectric delamination, and/or other damage to the glass substrate. As such, device yields are low.

Accordingly, embodiments disclosed herein may include a singulation process that requires minimal physical singulation through a glass core substrate. Such singulation processes are enabled through the removal of at least a portion of the glass material from the saw streets of a panel level glass substrate. For example, an etching process may be used in order to etch trenches into the panel level glass substrate within the saw street regions. In order to provide a continuous surface for subsequent buildup layer fabrication, a second glass panel is adhered to the panel level glass substrate to cover the trenches. This produces a cavity within the panel level glass substrate. After the buildup layers are fabricated, singulation may proceed with the saw street passing through the buildup layers to expose the underlying panel level glass substrate. Since the cavity is formed through the thickness of the glass substrate, only a small portion of the glass substrate needs to be mechanically separated (e.g., with a laser ablation process or the like). Since a smaller amount of glass is cut, the resulting damage to each glass core is significantly reduced.

In an embodiment, the resulting package substrates will have a distinctive profile along the edge surfaces. Particularly, a recess will be formed into an edge surface of the glass core substrate. For example, the recess may extend along a substantial portion of the thickness of the glass core substrate. In an embodiment, the recessed surfaces may have a substantially vertical profile (e.g., substantially parallel to the edge surface) or the recessed surfaces may be sloped or otherwise non-vertical. A sloped and/or non-vertical recessed surface may be the result of the etching process used to form the trenches into the surface of the panel level glass substrate.

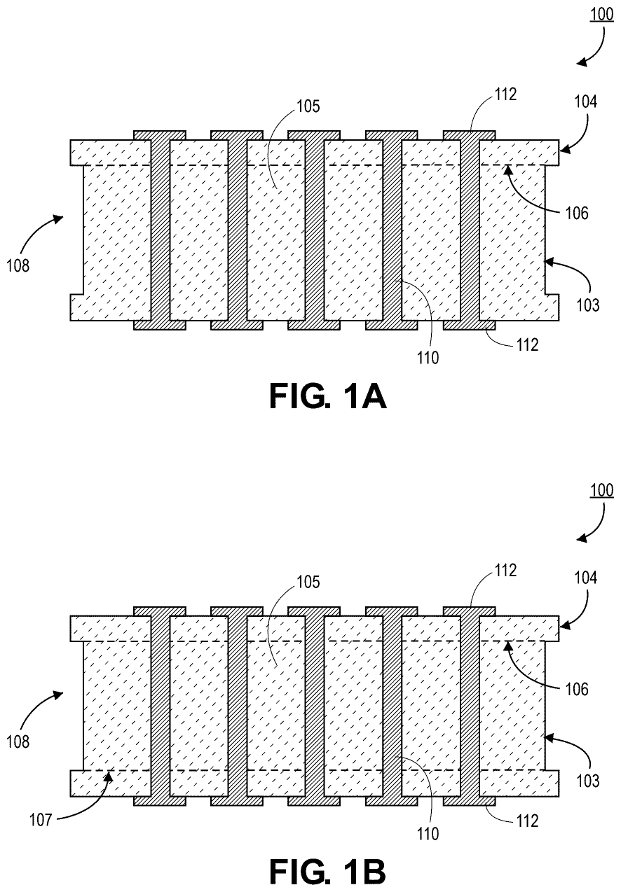

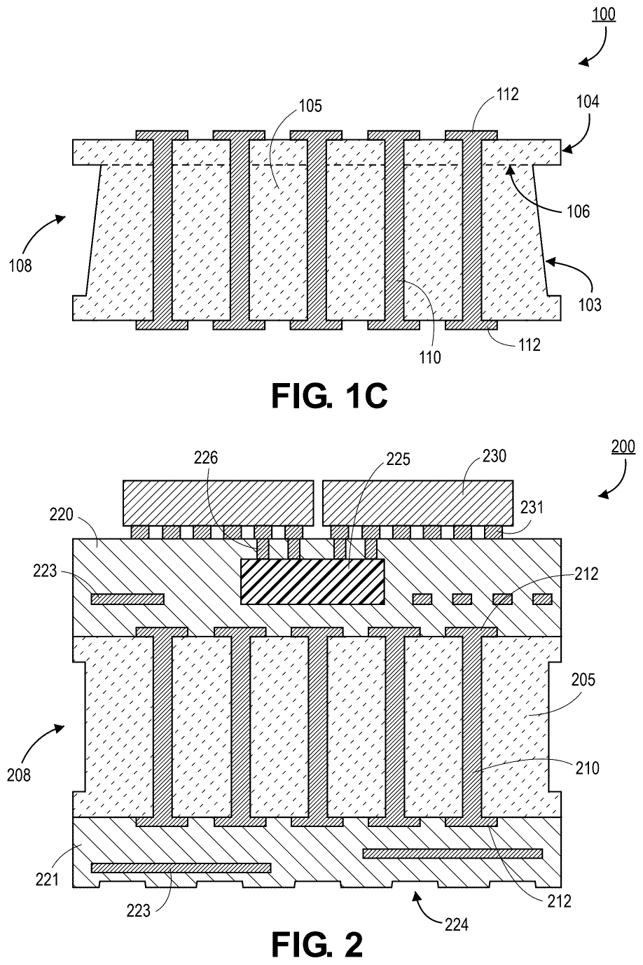

Referring now to FIG. 1A, a cross-sectional illustration of a portion of a package substrate 100 that includes a glass core substrate 105 is shown, in accordance with an embodiment. In an embodiment, the glass core substrate 105 may be substantially all glass. The glass core substrate 105 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, the glass core substrate 105 may be distinguished from, for example, the “prepreg” or “FR4” core of a Printed Circuit Board (PCB) substrate which typically comprises glass fibers embedded in a resinous organic material, such as an epoxy.

The glass core substrate 105 may have any suitable dimensions. In a particular embodiment, the glass core substrate 105 may have a thickness that is approximately 50 μm or greater. For example, the thickness of the glass core substrate 105 may be between approximately 50 μm and approximately 1.4 mm. Though, smaller or larger thicknesses may also be used. The glass core substrate 105 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core substrate 105 (from an overhead plan view) may be between approximately 10 mm×10 mm and approximately 250 mm×250 mm. In an embodiment, the glass core substrate 105 may have a first side that is perpendicular or orthogonal to a second side. In a more general embodiment, the glass core substrate 105 may comprise a rectangular prism volume with sections (e.g., vias) removed and filled with other materials (e.g., metal, etc.).

The glass core substrate 105 may comprise a single monolithic layer of glass. In other embodiments, the glass core substrate 105 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core substrate 105 may each have a thickness less than approximately 50 μm. For example, discrete layers of glass in the glass core substrate 105 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core substrate 105 may be any suitable glass formulation that has the necessary mechanical robustness and compatibility with semiconductor packaging manufacturing and assembly processes. For example, the glass core substrate 105 may comprise aluminosilicate glass, borosilicate glass, alumino-borosilicate glass, silica, fused silica, or the like. In some embodiments, the glass core substrate 105 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core substrate 105 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core substrate 105 may comprise at least 23 percent silicon (by weight) and at least 26 percent oxygen (by weight). In some embodiments, the glass core substrate 105 may further comprise at least 5 percent aluminum (by weight).

In an embodiment, the glass core substrate 105 may comprise one or more electrically conductive vias 110 that pass through a thickness of the glass core substrate 105. In the illustrated embodiment, the vias 110 have substantially vertical sidewalls. Though, in other embodiments, the sidewalls of the vias 110 may be sloped. For example, the vias 110 may have a tapered cross-sectional shape, or the vias 110 may have an hourglass shaped cross-section. Pads 112 may be provided over and/or under the vias 110. In an embodiment, the vias 110 and the pads 112 may comprise copper or any other suitable electrically conductive material.

In an embodiment, the glass core substrate 105 may comprise an edge surface 104. In an embodiment, a recess 108 may be formed into the edge surface 104. The recess 108 may be provided between a top and a bottom of the glass core substrate 105. In an embodiment, the recess 108 may have a recessed surface 103 that is set back from the edge surface 104. The recessed surface 103 may be set back from the edge surface 104 by a distance up to approximately 50 μm, up to approximately 25 μm, up to approximately 10 μm, or up to approximately 5 μm. Though, larger setbacks from the edge surface 104 may also be provided for the recessed surface 103. In an embodiment, a height of the recess 108 (as measured along a line between the bottom of the glass core substrate 105 and the top of the glass core substrate 105) is greater than the depth of the recess 108 into the edge surface 104.

In the illustrated embodiment, a surface of the glass core substrate 105 that connects the recessed surface 103 to the edge surface 104 may be substantially orthogonal to the edge surface 104. As used herein, “substantially orthogonal” may refer to an angle that is between 80° and 100°. In the illustrated embodiment, both the top and bottom of the recess 108 comprise substantially orthogonal connecting surfaces to the edge surface 104. Though, in other embodiments, at least one of the connecting surfaces may not be substantially orthogonal to the edge surface 104. Additionally, while the connecting surfaces are both shown as being linear, at least one of the connecting surfaces may be curved or otherwise non-linear in some embodiments.

In the illustrated embodiment, the recess 108 is substantially centered along a thickness of the glass core substrate 105. That is, a distance between a top of the glass core substrate 105 and a top of the recess 108 is substantially equal to a distance between a bottom of the glass core substrate and a bottom of the recess 108. Though, in other embodiments, the recess 108 may be offset from a midpoint of the glass core substrate 105. In an embodiment, a length of the recess 108 in a direction from a top of the recess 108 to a bottom of the recess 108 (as shown in FIG. 1A) may be greater than a length of the edge surface 104 in the same direction. In some instances, the length of the edge surface 104 may include a combined length of the edge surface 104 above and below the recess 108.

In an embodiment, the recessed surface 103 is shown as being substantially vertical. That is, the recessed surface 103 may be substantially orthogonal to the top and/or bottom surface of the glass core substrate 105. In some embodiments, the recessed surface 103 may be provided along a plane that is substantially parallel to a plane that comprises the edge surface 104. Though, as will be described in greater detail herein, recessed surfaces 103 with different profiles relative to the edge surface 104 may also be used in some embodiments.

In an embodiment, the edge surface 104 may have a different surface roughness than the recessed surface 103. The difference in surface roughness may be the result of different subtractive processes used to form the edge surface 104 and the recessed surface 103. For example, the recessed surface 103 may be formed with an etching process (e.g., a wet etching process or the like), and the edge surface 104 may be formed with a laser ablation process or the like. In such an embodiment, the edge surface 104 may have a surface roughness that is greater than a surface roughness of the recessed surface 103.

In the illustrated embodiment, a seam 106 is illustrated within the glass core substrate 105. The seam 106 may be substantially parallel to a top (or bottom) surface of the glass core substrate 105. In an embodiment, the seam 106 may be the result of a glass-to-glass fusion process that is used in order to improve the singulation process (as will be described in greater detail herein). In some embodiments, the seam 106 may be positioned at the same height within the glass core substrate 105 as a top surface of the recess 108. While a seam 106 is shown in FIG. 1A, it is to be appreciated that the seam 106 may not be visible, or only portions of the seam 106 may be visible in some embodiments.

Referring now to FIG. 1B, a cross-sectional illustration of a portion of a package substrate 100 that comprises a glass core substrate 105 is shown, in accordance with an additional embodiment. In an embodiment, the glass core substrate 105 in FIG. 1B may be substantially similar to the glass core substrate 105 in FIG. 1A, with the exception of an additional seam 107. In an embodiment, a second seam 107 may be included at an opposite end of the recess 108 from the seam 106. For example, seam 106 is positioned at the top of the recess 108, and the seam 107 is positioned at the bottom of the recess 108.

In an embodiment, the seam 107 may also be the result of a glass-to-glass fusion process that may be used in some embodiments. That is, embodiments may include a first glass fusion process and a second glass fusion process. Similar to seam 106, some portions of the seam 107 may not be visible or none of the seam 107 may be visible in some embodiments.

Referring now to FIG. 1C, a cross-sectional illustration of a package substrate 100 that includes a glass core substrate 105 is shown, in accordance with an additional embodiment. In an embodiment, the glass core substrate 105 in FIG. 1C may be similar to the glass core substrate 105 in FIG. 1A, with the exception of the recessed surface 103. Instead of having a substantially vertical profile, the recessed surface 103 in FIG. 1C includes a sloped profile. That is, the recessed surface 103 may be provided along a plane that intersects a plane that includes the edge surface 104. The recessed surface 103 may be linear or the recessed surface 103 may be curved or have any other non-liner profile from the top of the recess 108 to the bottom of the recess 108.

In FIG. 1C, the seam 106 is shown at the top of the glass core substrate 105, and there is no seam at the bottom of the recess 108. The positioning of the sloped recessed surface 103 may result in the width of the glass core substrate 105 at the top of the recess 108 (proximate to the seam 106) being narrower than a width of the sloped recessed surface 103 at a bottom of the recess 108 (away from the seam 106). Though, in other embodiments, there may also be a seam at the bottom of the recess 108 (e.g., similar to the seam 107 shown in FIG. 1B).

Referring now to FIG. 2, a cross-sectional illustration of a package substrate 200 is shown, in accordance with an embodiment. In an embodiment, the package substrate 200 may comprise a glass core substrate 205. In an embodiment, the glass core substrate 205 may be similar to any of the glass core substrates described in greater detail herein. For example, vias 210 may pass through a thickness of the glass core substrate 205. In an embodiment, a recess 208 may be provided into an edge surface of the glass core substrate 205. In an embodiment, the recess 208 may include a vertical recessed surface, a sloped recessed surface, or a curved recessed surface. The recess 208 may be similar to any of the recesses described in greater detail herein. While no seam is shown in the glass core substrate 205, embodiments may include a seam similar to any of those described herein.

In an embodiment, a buildup layers 220 may be provided over the glass core substrate 205. In an embodiment, the buildup layer 220 may comprise an organic dielectric material, such as an organic buildup film or the like. In an embodiment, pads 212, traces 223, vias, and/or the like may be embedded within the buildup layer 220 in order to provide electrical routing within the package substrate 200. In an embodiment, openings 224 may be provided in a bottom buildup layer 221 provided below the glass core substrate 205. The bottom buildup layer 221 may be similar to the buildup layer 220. In an embodiment, a width of the buildup layers 220 and/or 221 may be substantially similar to a width of the glass core substrate 205 above and/or below the recess 208.

In an embodiment, one or more dies 230 may be coupled to the buildup layer 220 by interconnects 231. The interconnects 231 may comprise any suitable first level interconnect (FLI) architecture, such as solder, copper bumps, hybrid bonding, or the like. In an embodiment, the one or more dies 230 may comprise any type of die, such as a processor (e.g., a central processing unit (CPU), a graphics processing unit (GPU), an XPU, etc.) a memory die, a communications die, or the like. In some embodiments, two or more dies 230 may be electrically coupled together through the buildup layer 220. For example, a bridge die 225 (sometimes called a bridge for short) may be embedded within the buildup layer 220. The bridge 225 may be a semiconductor substrate, a glass substrate, or the like that comprises electrically conductive routing (e.g., copper traces) on and/or embedded within the bridge 225. In an embodiment, vias 226 through a portion of the buildup layer 220 may electrically couple each die 230 to the bridge 225. As such, an electrical path from a first die 230 may pass through and/or over the bridge 225 to a second die 230.

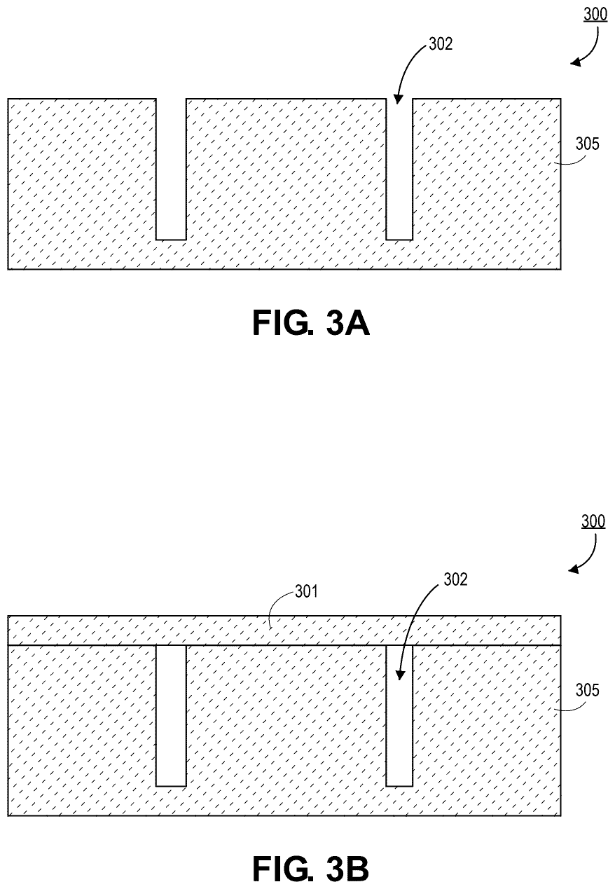

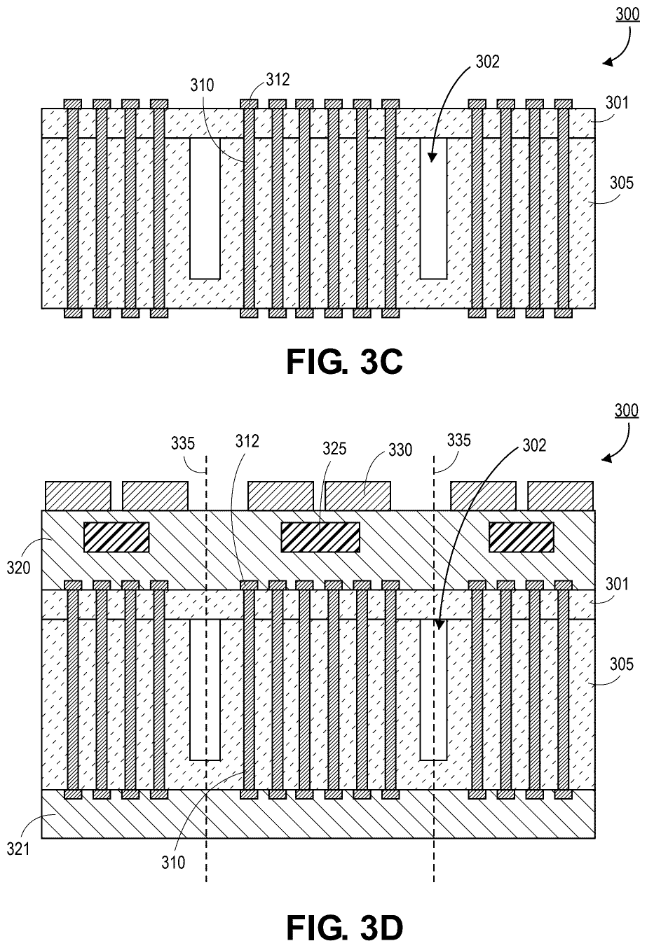

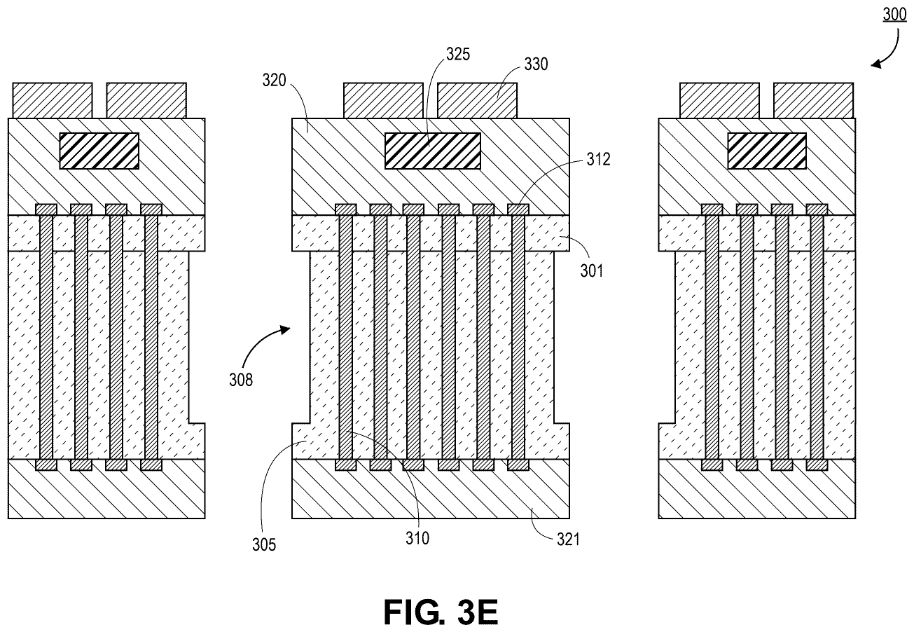

Referring now to FIG. 3A-3E, a series of cross-sectional illustrations depicting a process for forming a package substrate 300 with a glass core substrate 305 with simplified singulation through the glass core substrate 305 is shown, in accordance with an embodiment.

Referring now to FIG. 3A, a cross-sectional illustration of a portion of a package substrate 300 at a stage of manufacture is shown, in accordance with an embodiment. In an embodiment, the package substrate 300 may comprise a glass core substrate 305. The glass core substrate 305 may be similar to any of the glass core substrates described in greater detail herein. In an embodiment, a plurality of trenches 302 may be formed into a surface of the glass core substrate 305. The trenches 302 may pass into, but not through, the glass core substrate 305 in some embodiments. The trenches 302 may be formed along regions of the glass core substrate 305 that will ultimately become the saw streets between a plurality of package substrates 300.

The trenches 302 may have any suitable sidewall profile. For example, in FIG. 3A, the trenches 302 may have substantially vertical sidewalls. Though, in other embodiments, the sidewalls may be tapered, curved, or the like. For example, a top of the trench 302 by the surface may be wider than a bottom of the trench 302 within the glass core substrate 305. The profile of the trenches 302 may be dictated by the processing operation used to form the trenches 302. For example, a laser assisted patterning process (e.g., a laser exposure of selected regions followed by a wet etching process) may result in a tapered trench with an opening that is wider than a bottom of the trench 302.

Referring now to FIG. 3B, a cross-sectional illustration of the package substrate 300 after a glass layer 301 is provided over the glass core substrate 305 is shown, in accordance with an embodiment. In an embodiment, the glass layer 301 may extend across the trenches 302. Accordingly, the trenches 302 are substantially sealed in order to form a void between the glass core substrate 305 and the glass layer 301. The void may be filled with a gas, such as air or the like. In other embodiments, a dielectric material (e.g., a mold material, an epoxy material, or the like) may be inserted into the trenches before the glass layer 301 is adhered to the glass core substrate 305. As such, the void may be filled with a dielectric material in some embodiments. In an embodiment, the glass layer 301 may be fused to the glass core substrate 305 with any suitable process. In some instances, the fusing process may result in a seam between the glass core substrate 305 and the glass layer 301. Though, in other embodiments, a seam may not be visible when a fusion process is used to attach the glass layer 301 to the glass core substrate 305. In an embodiment, the glass layer 301 may comprise a material composition similar to the material composition of the glass core substrate 305. Though, the glass layer 301 may also have a different composition than the glass core substrate 305 in some embodiments. While the glass core substrate 305 and the glass layer 301 are referred to separately in FIG. 3A-3E, in some embodiments, the combination of the glass core substrate 305 and the glass layer 301 may be considered as being the glass core substrate 305.

Referring now to FIG. 3C, a cross-sectional illustration of the package substrate 300 after vias 310 are formed through the glass core substrate 305 and the glass layer 301 is shown, in accordance with an embodiment. As shown, the vias 310 may pass through an entire thickness of both the glass core substrate 305 and the glass layer 301. The vias 310 may be formed with any suitable patterning and plating process. For example, a laser assisted patterning process may be used to form via openings, and an electrochemical plating process may be used to deposit metal (e.g., copper) in the via openings. In the illustrated embodiment, the vias 310 have vertical sidewalls. Other embodiments may include vias 310 with tapered sidewalls, an hourglass shaped cross-section, and/or the like. In an embodiment, pads 312 may also be formed over and/or under the vias 310.

Referring now to FIG. 3D, a cross-sectional illustration of the package substrate 300 after buildup layers 320 and 321 are formed over the glass core substrate 305 and the glass layer 301 is shown, in accordance with an embodiment. In an embodiment, the buildup layers 320 and 321 may be similar to any of the buildup layers described in greater detail herein. Electrical routing (e.g., pads, traces, vias, etc.) within the buildup layers 320 and 321 are omitted from FIG. 3D for simplicity. In an embodiment, a bridge die 325 may be provided on and/or embedded within the buildup layer 320 in order to electrically couple dies 330 together. FIG. 3D illustrates the locations of saw streets 335 that pass through the trenches 302 between individual units of a panel.

Referring now to FIG. 3E, a cross-sectional illustration of the package substrate 300 after singulation along the saw streets 335 is shown, in accordance with an embodiment. In an embodiment, the singulation process may include a laser ablation process. As can be appreciated, the laser ablation only needs to pass through a relatively small amount of glass (compared to a total thickness of the glass core substrate 305 and the glass layer 301). As such, potential damage to the glass core substrate 305 and the glass layer 301 is minimized. Due to the trench 302 along the saw streets 335, the singulation process may result in the formation of recesses 308 along the edge surface of the package substrate 300. The recesses 308 may be similar to any of the recesses described in greater detail herein. In embodiments, where the void was filled with a dielectric material, the singulation process may also result in the formation of a dielectric plug that fills the recess 308. In such an embodiment, an outer edge of the dielectric plug may be substantially coplanar with an edge surface of the glass core substrate 305.

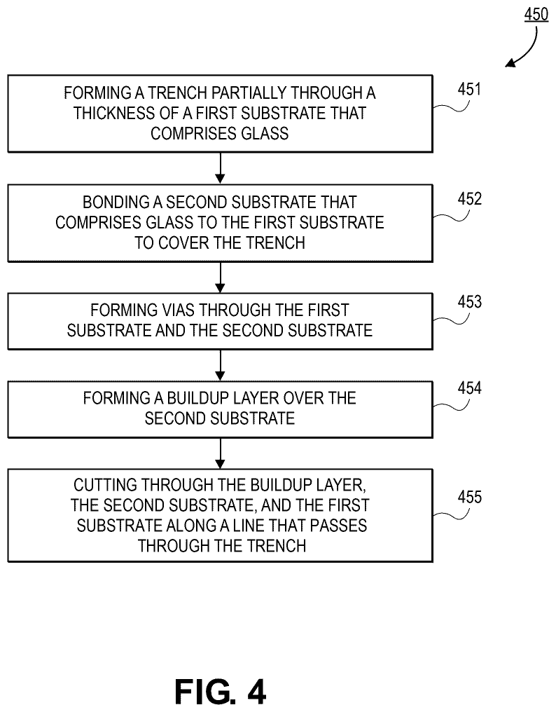

Referring now to FIG. 4, a flow diagram depicting a process 450 for forming a package substrate with a glass core that comprises a recess is shown, in accordance with an embodiment. In an embodiment, the process 450 may be similar to the process described with respect to FIG. 3A-3E.

In an embodiment, the process 450 may begin with operation 451, which comprises forming a trench partially through a thickness of a first substrate that comprises glass. In an embodiment, the first substrate may be similar to any of the glass core substrates described in greater detail herein. In an embodiment, the trench may have vertical sidewalls, tapered sidewalls, curved sidewalls, or the like. The trench may be formed with any suitable patterning process, such as a laser assisted etching process.

In an embodiment, the process 450 may continue with operation 452, which comprises bonding a second substrate that comprises glass to the first substrate to cover the trench. In an embodiment, the second substrate may be similar in composition to the composition of the first substrate. In an embodiment, a fusion process may be used to attach the first substrate to the second substrate.

In an embodiment, the process 450 may continue with operation 453, which comprises forming vias through the first substrate and the second substrate. In an embodiment, the vias may be formed with any suitable patterning and plating processes.

In an embodiment, the process 450 may continue with operation 454, which comprises forming a buildup layer over the second substrate. In an embodiment, the buildup layer may comprise an organic buildup film or the like. Electrical routing (e.g., pads, vias, traces, etc.) may be fabricated within the buildup layer. In some embodiments, a bridge die may also be provided within the buildup layer.

In an embodiment, the process 450 may continue with operation 455, which comprises cutting through the buildup layer, the second substrate, and the first substrate along a line that passes through the trench. In an embodiment, the cutting process may sometimes be referred to as a singulation process. The singulation process may comprise a laser ablation process or the like. Since the line passes through the trench, only a small portion of the glass material is cut relative to a combined thickness of the first substrate and the second substrate. For example, a percentage of the combined thickness of the first substrate and the second substrate that is cut during the singulation process may be up to approximately 50%, up to approximately 20%, up to approximately 10%, or up to approximately 5%. The presence of the trench may also result in a package substrate with a recess formed along an edge surface of the package substrate.

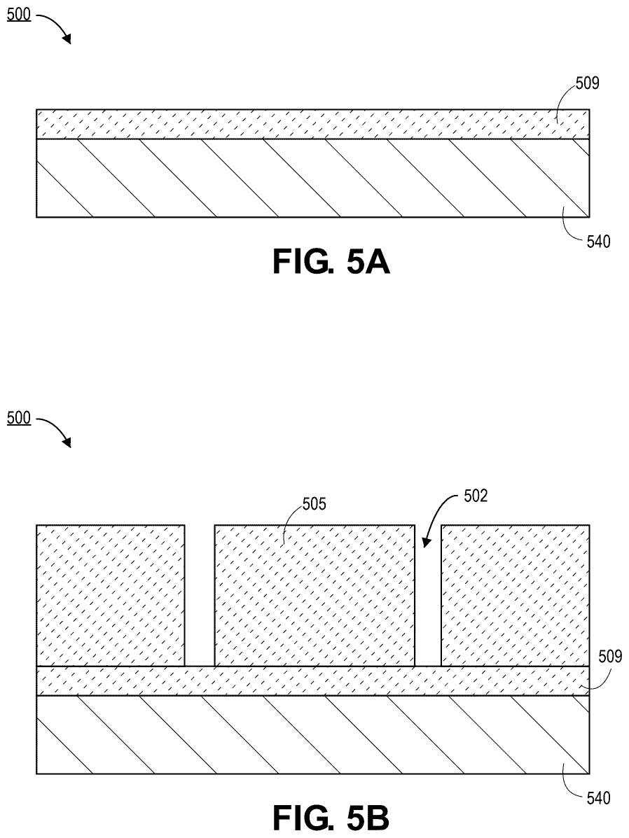

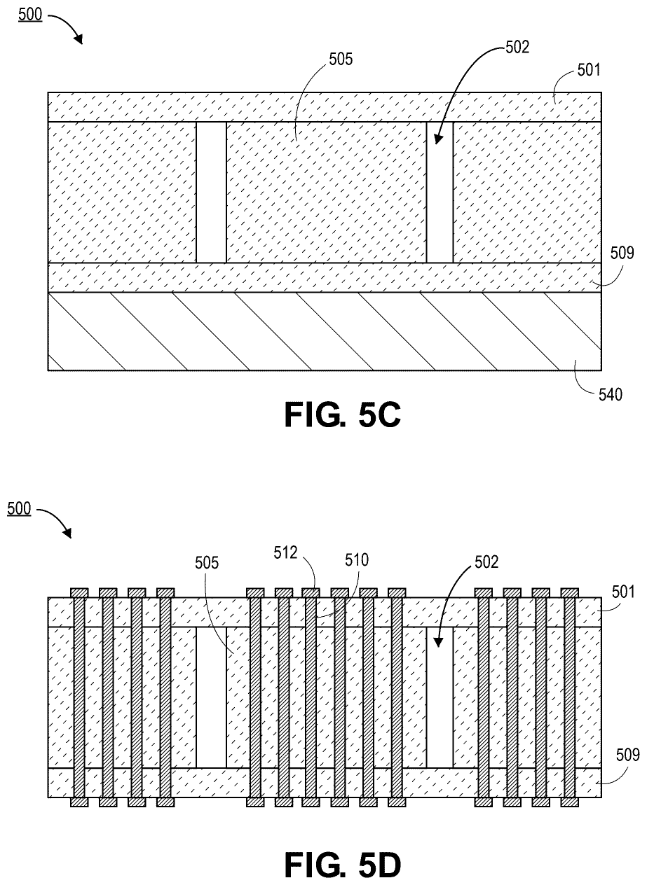

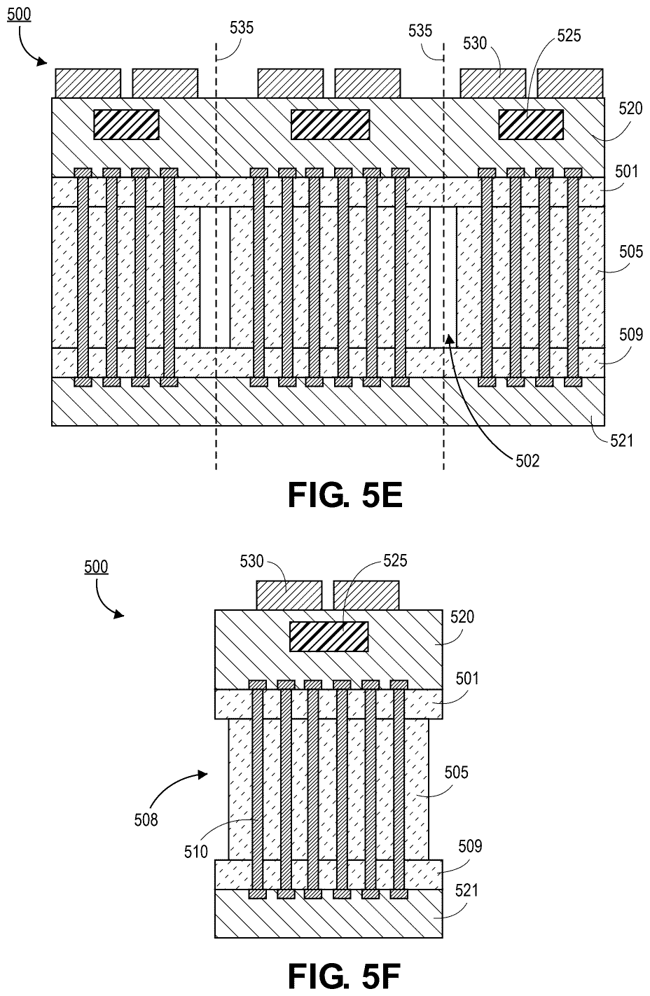

Referring now to FIG. 5A-5F, a series of cross-sectional illustrations depicting a process for forming a package substrate 500 with a glass core with a recess 508 is shown, in accordance with an additional embodiment.

Referring now to FIG. 5A, a cross-sectional illustration of a portion of a package substrate 500 at a stage of manufacture is shown, in accordance with an embodiment. As shown, a first glass layer 509 is supported by a carrier 540. The first glass layer 509 may be similar to any of the glass substrates described in greater detail herein. The carrier 540 may be a rigid and dimensionally stable substrate with a flat surface, such as a glass substrate, a metal substrate, a semiconductor substrate, or the like.

Referring now to FIG. 5B, a cross-sectional illustration of the package substrate 500 after a plurality of second glass layers 505 are bonded to the first glass layer 509 is shown, in accordance with an embodiment. In an embodiment, the second glass layers 505 have a width that is narrower than a width of the first glass layer 509. In an embodiment, the second glass layers 505 are spaced apart from each other by a gap 502. The plurality of second glass layers 505 may be fusion bonded to the first glass layer 509 in some embodiments. In some instances, the fusing process may result in a seam between the plurality of second glass layers 505 and the first glass layer 509. Though, in other embodiments, a seam may not be visible when a fusion process is used to attach the plurality of second glass layers 505 to the first glass layer 509.

Referring now to FIG. 5C, a cross-sectional illustration of the package substrate 500 after a third glass layer 501 is provided over the plurality of second glass layers 505 is shown, in accordance with an embodiment. In an embodiment, the third glass layer 501 may extend across the gaps 502. Accordingly, the gaps 502 are substantially sealed in order to form a void between the first glass layer 509, the plurality of second glass layers 505, and the third glass layer 501. In an embodiment, the third glass layer 501 may be fused to the plurality of second glass layers 505 with any suitable process. In some instances, the fusing process may result in a seam between the plurality of second glass layers 505 and the third glass layer 501. Though, in other embodiments, a seam may not be visible when a fusion process is used to attach the third glass layer 501 to the plurality of second glass layers 505. In an embodiment, the third glass layer 501 may comprise a material composition similar to the material composition of the plurality of second glass layers 505 and/or the first glass layer 509. Though, the third glass layer 501 may also have a different composition than the plurality of second glass layers 505 and/or the first glass layer 509 in some embodiments. While the first glass layer 509, the plurality of second glass layers 505, and the third glass layer 501 are referred to separately in FIG. 5A-5F, in some embodiments, the combination of the three glass layers 509, 505, and 501 may be considered as being a glass core substrate.

Referring now to FIG. 5D, a cross-sectional illustration of the package substrate 500 after vias 510 are formed through the glass layers 509, 505, and 501 is shown, in accordance with an embodiment. As shown, the vias 510 may pass through an entire thickness of all three of the glass layers 509, 505, and 501. The vias 510 may be formed with any suitable patterning and plating process. For example, a laser assisted patterning process may be used to form via openings, and an electrochemical plating process may be used to deposit metal (e.g., copper) in the via openings. In the illustrated embodiment, the vias 510 have vertical sidewalls. Other embodiments may include vias 510 with tapered sidewalls, an hourglass shaped cross-section, and/or the like. In an embodiment, pads 512 may also be formed over and/or under the vias 510.

Referring now to FIG. 5E, a cross-sectional illustration of the package substrate 500 after buildup layers 520 and 521 are formed and the third glass layer 501 is shown, in accordance with an embodiment. In an embodiment, the buildup layers 520 and 521 may be similar to any of the buildup layers described in greater detail herein. Electrical routing (e.g., pads, traces, vias, etc.) within the buildup layers 520 and 521 are omitted from FIG. 5E for simplicity. In an embodiment, a bridge die 525 may be provided on and/or embedded within the buildup layer 520 in order to electrically couple dies 530 together. FIG. 5E illustrates the locations of saw streets 535 that pass through the gaps 502 between individual units of a panel.

Referring now to FIG. 5F, a cross-sectional illustration of the package substrate 500 after singulation along the saw streets 535 is shown, in accordance with an embodiment. In an embodiment, the singulation process may include a laser ablation process. As can be appreciated, the laser ablation only needs to pass through the first glass layer 509 and the third glass layer 501. As such, potential damage to the plurality of second glass layers 505 is minimized. Due to the gap 502 along the saw streets 535, the singulation process may result in the formation of recesses 508 along the edge surface of the package substrate 500. The recesses 508 may be similar to any of the recesses described in greater detail herein.

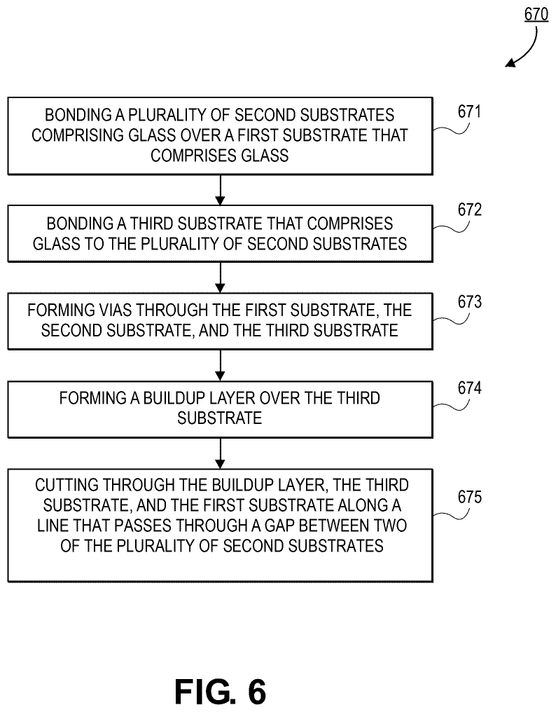

Referring now to FIG. 6, a flow diagram describing a process 670 for forming a package substrate with a glass core that comprises a recess is shown, in accordance with an embodiment. In an embodiment, the process 670 may be similar to the process described with respect to FIG. 5A-5F.

In an embodiment, the process 670 may begin with operation 671, which comprises bonding a plurality of second substrates comprising glass over a first substrate that comprises glass. In an embodiment, the bonding may include a fusion bonding process. In an embodiment, at least two of the plurality of second substrates are spaced apart from each other by a gap. A thickness of each of the plurality of second substrates may be greater than a thickness of the first substrate.

In an embodiment, the process 670 may continue with operation 672, which comprises bonding a third substrate that comprises glass to the plurality of second substrates. In an embodiment, the third substrate may be fusion bonded to the plurality of second substrates. The third substrate may extend over the gap in order to form a cavity defined by surfaces of the first substrate, the second substrate, and the third substrate.

In an embodiment, the process 670 may continue with operation 673, which comprises forming vias through the first substrate, the second substrate, and the third substrate. In an embodiment, the vias may be formed with any suitable patterning and plating processes.

In an embodiment, the process 670 may continue with operation 674, which comprises forming a buildup layer over the third substrate. In an embodiment, the buildup layer may comprise an organic buildup film or the like. Electrical routing (e.g., pads, vias, traces, etc.) may be fabricated within the buildup layer. In some embodiments, a bridge die may also be provided within the buildup layer.

In an embodiment, the process 670 may continue with operation 675, which comprises cutting through the buildup layer, the third substrate, and the first substrate along a line that passes through the gap between the two of the plurality of second substrates. In an embodiment, the cutting process may sometimes be referred to as a singulation process. The singulation process may comprise a laser ablation process or the like. Since the cut line passes through the gap, only a small portion of the glass material is cut relative to a combined thickness of the first substrate, the second substrate, and the third substrate. For example, a percentage of the combined thickness of the first substrate, the second substrate, and the third substrate that is cut during the singulation process may be up to approximately 50%, up to approximately 20%, up to approximately 10%, or up to approximately 5%. The presence of the gap may also result in a package substrate with a recess formed along an edge surface of the package substrate.

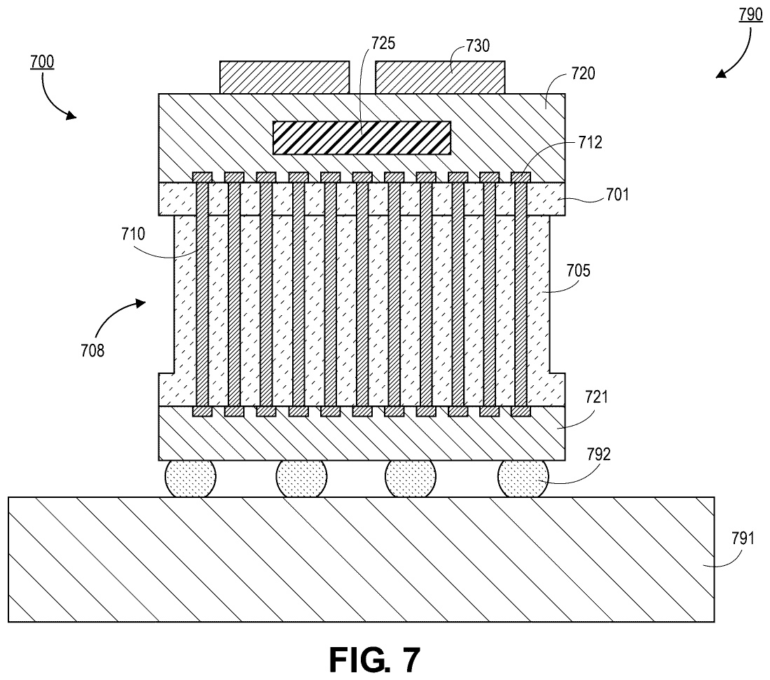

Referring now to FIG. 7, a cross-sectional illustration of an electronic system 790 is shown, in accordance with an embodiment. In an embodiment, the electronic system 790 may comprise a board 791, such as a printed circuit board (PCB), a motherboard, or the like. In an embodiment, the board 791 may be electrically coupled to a package substrate 700 by interconnects 792. The interconnects 792 may comprise solder balls, sockets, pins, or any other suitable second level interconnect (SLI) architecture.

In an embodiment, the package substrate 700 may be similar to any of the package substrates described in greater detail herein. For example, the package substrate 700 may comprise a glass core substrate 705 between buildup layers 720 and 721. A glass layer 701 may also be fused to the glass core substrate 705 in some embodiments. In an embodiment, a recess 708 may be formed along an edge surface of the glass core substrate 705. Vias 710 may pass through the glass core substrate 705 and pads 712 may be provided over and/or under the vias 710.

In an embodiment, one or more dies 730 may be electrically coupled to the package substrate 700 through interconnects (not shown). In an embodiment, the interconnects may comprise solder balls, copper bumps, hybrid bonding interfaces, or any other suitable FLI architecture. In an embodiment, the one or more dies 730 may comprise any type of die, such as processor (e.g., a central processing unit (CPU), a graphics processing unit (GPU), an XPU, etc.), a memory die, a communications die, and/or the like. In some embodiments, a bridge 725 that is embedded in the buildup layer 720 or provided over the buildup layer 720 may electrically couple two dies 730 together. That is, an electrically conductive path may be provided from a first die 730 to a second die 730, and the electrically conductive path may pass through and/or over the bridge 725.

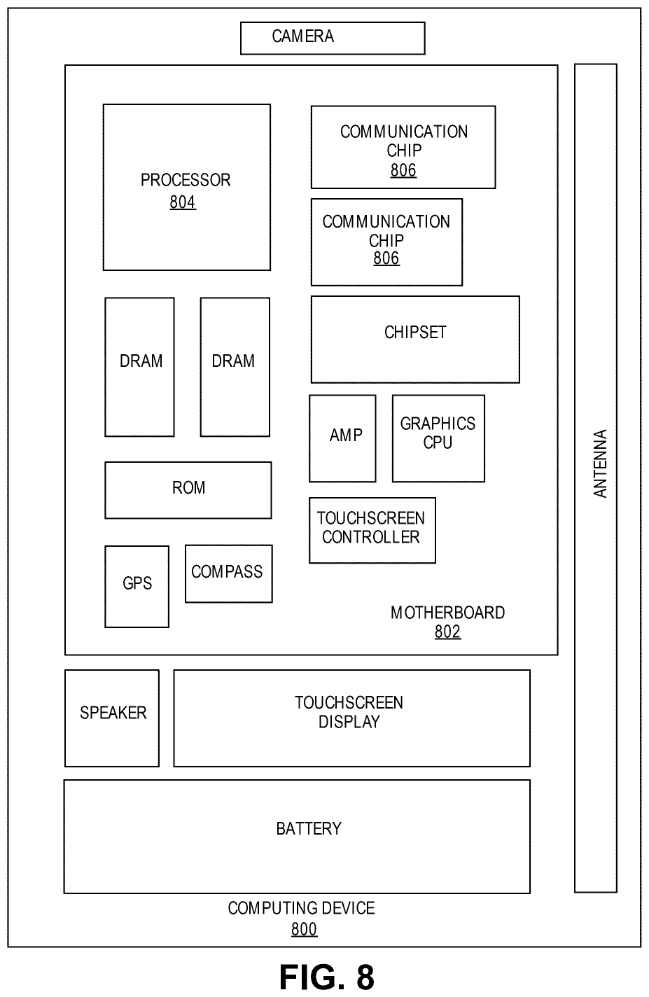

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that comprises a package substrate with a glass core that includes a recess along an edge surface of the glass core substrate, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that comprises a package substrate with a glass core that includes a recess along an edge surface of the glass core substrate, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate with an edge surface, wherein the substrate comprises a glass layer; a via through a thickness of the substrate; and a recess into the edge surface, wherein a height of the recess measured in a direction from a bottom of the substrate to a top of the substrate is greater than a depth of the recess.

Example 2: the apparatus of Example 1, wherein a surface of the recess is substantially parallel to the edge surface.

Example 3: the apparatus of Example 1 or Example 2, wherein at least a portion of a surface of the recess is along a first plane and at least a portion of a surface of the edge surface is along a second plane, wherein the first plane intersects the second plane.

Example 4: the apparatus of Examples 1-3, wherein a surface of the recess is coupled to the edge surface by a connecting surface that is substantially orthogonal to the edge surface.

Example 5: the apparatus of Examples 1-4, wherein the substrate comprises a seam that is substantially orthogonal to the edge surface.

Example 6: the apparatus of Example 5, wherein the seam is positioned at a top or bottom of the recess.

Example 7: the apparatus of Example 5 or Example 6, further comprising a second seam, and wherein the seam is positioned at a top of the recess and the second seam is positioned at a bottom of the recess.

Example 8: the apparatus of Examples 1-7, wherein the edge surface has a first surface roughness and a surface of the recess has a second surface roughness that is different than the first surface roughness.

Example 9: the apparatus of Examples 1-8, wherein the recess has a first length in a direction and the edge surface has a second length in the direction, wherein the first length is greater than the second length.

Example 10: the apparatus of Examples 1-9, wherein the recess is filled with a dielectric plug, and wherein an outer surface of the dielectric plug is substantially coplanar with the edge surface.

Example 11: an apparatus, comprising: a substrate, wherein the substrate comprises a glass layer; a recess into an edge surface of the substrate between a first surface of the substrate and a second surface of the substrate; a layer over the first surface of the substrate, wherein the layer comprises an organic dielectric material.

Example 12: the apparatus of Example 11, wherein a width of the layer is substantially equal to a width of the substrate.

Example 13: the apparatus of Example 11 or Example 12, wherein the recess has a surface that is substantially parallel to the edge surface.

Example 14: the apparatus of Examples 11-13, wherein the recess has a surface that is not substantially parallel to the edge surface.

Example 15: the apparatus of Examples 11-14, wherein the substrate comprises a seam that is substantially parallel to the first surface of the substrate.

Example 16: the apparatus of Examples 11-15, wherein the edge surface has a first surface roughness and a recessed surface of the recess has a second surface roughness that is less than the first surface roughness.

Example 17: the apparatus of Examples 11-16, further comprising: a die embedded in the layer, wherein the die comprises electrically conductive routing.

Example 18: an apparatus, comprising: a package substrate, wherein the package substrate comprises: a glass core, wherein the glass core comprises an edge with a first portion that has a first surface roughness and a second portion that has a second surface roughness that is different than the first surface roughness; and an organic buildup layer over the glass core, wherein a bridge die is embedded in the organic buildup layer; and a first die and a second die that are both coupled to the package substrate, wherein the bridge die electrically couples the first die to the second die.

Example 19: the apparatus of Example 18, further comprising: a board coupled to a surface of the package substrate opposite from the first die and the second die.

Example 20: the apparatus of Example 18 or Example 19, wherein the second portion has a sloped profile relative to a profile of the first portion.

What is claimed is:

1. An apparatus, comprising:
a substrate with an edge surface, wherein the substrate comprises a glass layer;
a via through a thickness of the substrate; and
a recess into the edge surface, wherein a height of the recess measured in a direction from a bottom of the substrate to a top of the substrate is greater than a depth of the recess.

2. The apparatus of claim 1, wherein a surface of the recess is substantially parallel to the edge surface.

3. The apparatus of claim 1, wherein at least a portion of a surface of the recess is along a first plane and at least a portion of a surface of the edge surface is along a second plane, wherein the first plane intersects the second plane.

4. The apparatus of claim 1, wherein a surface of the recess is coupled to the edge surface by a connecting surface that is substantially orthogonal to the edge surface.

5. The apparatus of claim 1, wherein the substrate comprises a seam that is substantially orthogonal to the edge surface.

6. The apparatus of claim 5, wherein the seam is positioned at a top or bottom of the recess.

7. The apparatus of claim 5, further comprising a second seam, and wherein the seam is positioned at a top of the recess and the second seam is positioned at a bottom of the recess.

8. The apparatus of claim 1, wherein the edge surface has a first surface roughness and a surface of the recess has a second surface roughness that is different than the first surface roughness.

9. The apparatus of claim 1, wherein the recess has a first length in a direction and the edge surface has a second length in the direction, wherein the first length is greater than the second length.

10. The apparatus of claim 1, wherein the recess is filled with a dielectric plug, and wherein an outer surface of the dielectric plug is substantially coplanar with the edge surface.

11. An apparatus, comprising:
a substrate, wherein the substrate comprises a glass layer;
a recess into an edge surface of the substrate between a first surface of the substrate and a second surface of the substrate;
a layer over the first surface of the substrate, wherein the layer comprises an organic dielectric material.

12. The apparatus of claim 11, wherein a width of the layer is substantially equal to a width of the substrate.

13. The apparatus of claim 11, wherein the recess has a surface that is substantially parallel to the edge surface.

14. The apparatus of claim 11, wherein the recess has a surface that is not substantially parallel to the edge surface.

15. The apparatus of claim 11, wherein the substrate comprises a seam that is substantially parallel to the first surface of the substrate.

16. The apparatus of claim 11, wherein the edge surface has a first surface roughness and a recessed surface of the recess has a second surface roughness that is less than the first surface roughness.

17. The apparatus of claim 11, further comprising:
a die embedded in the layer, wherein the die comprises electrically conductive routing.

18. An apparatus, comprising:
a package substrate, wherein the package substrate comprises:
a glass core, wherein the glass core comprises an edge with a first portion that has a first surface roughness and a second portion that has a second surface roughness that is different than the first surface roughness; and
an organic buildup layer over the glass core, wherein a bridge die is embedded in the organic buildup layer; and
a first die and a second die that are both coupled to the package substrate, wherein the bridge die electrically couples the first die to the second die.

19. The apparatus of claim 18, further comprising:
a board coupled to a surface of the package substrate opposite from the first die and the second die.

20. The apparatus of claim 18, wherein the second portion has a sloped profile relative to a profile of the first portion.
